(19) United States
(12) Patent Application Publication
(10) Pub. No.: US 2008/0261120 A1
(43) Pub. Date: Oct. 23, 2008

(54) PHOTOLITHOGRAPHY MASK WITH INTEGRALLY FORMED PROTECTIVE CAPPING LAYER

(76) Inventors: Jeffrey Peter Gambino, Westford, VT (US); Robert Kenneth Leidy, Burlington, VT (US); Kirk David Peterson, Jericho, VT (US); Jed Hickory Rankin, Richmond, VT (US); Edmund Juris Sprogis, Underhill, VT (US)

Correspondence Address: SCHMEISER, OLSEN & WATTS, 22 CENTURY HILL DRIVE, SUITE 302, LATHAM, NY, 12110, US

(21) Appl. No.: 11/737,956

(22) Filed: Apr. 20, 2007

(51) Int. Cl. G03C 5/00; G03F 1/00

(52) U.S. Cl. 430/5; 430/322; 430/323; 430/324; 430/394

(57) ABSTRACT

A photomask and a method of fabricating the photomask. The photomask including: a substrate transparent to a selected wavelength or wavelengths of radiation, the substrate having a top surface and an opposite bottom surface, the substrate having a printable region and a non-printable region; the printable region having first opaque regions raised above the top surface of the substrate adjacent to clear regions, each opaque region of the first opaque regions having sidewalls and opposite top and bottom surfaces, the first opaque regions including a metal; the non-printable region including metal second opaque region raised above the top surface of the substrate, the second opaque region having sidewalls and opposite top and bottom surface, the second opaque regions including the metal; and a conformal protective metal oxide capping layer on top surfaces and sidewalls of the first and second opaque regions. The conformal layer is formed by oxidation.

### FIELD OF THE INVENTION

The present invention relates to the field of photomasks for the manufacture of integrated circuits; more specifically, it relates to a photomask for the manufacture of integrated circuits and to a method of fabricating the photomask mask.

### BACKGROUND OF THE INVENTION

Integrated circuit fabrication utilizes photolithography masks having opaque and clear areas corresponding to features on an integrated circuit that the mask is used to fabricate. Generally several masks, each having a pattern of clear and opaque areas corresponding to a particular fabrication level are required to build a functional semiconductor device. In use, a photosensitive layer (hereinafter photoresist layer) on an integrated circuit substrate (hereinafter wafer) is exposed to optical radiation projected through the photomask to form latent images in the photoresist layer. After developing the photoresist layer, a positive or negative pattern (relative to the pattern of clear and opaque regions on the photomask) comprising islands of photoresist is reproduced on the wafer.

One type of photolithographic mask is called a binary mask (as opposed to a phase shift mask) in which there are two levels of transmission and no phase change of the radiation passing through the mask, one level in the opaque regions that essentially blocks the optical radiation and one level in the clear regions that passes the optical radiation.

A second type of mask is called an alternating phase shift mask having three levels of transmission, one level in the clear regions that essentially blocks the optical radiation, a second level in clear regions that passes the optical radiation and a third level that passes and phase-shifts the optical radiation by 180 degrees compared to the optical radiation passing through the thin substrate clear regions.

In such masks, it is necessary to ensure that the relative transmission levels and/or optical radiation wavelength phase do not change if consistent image reproduction is to be consistent from wafer to wafer.

### SUMMARY OF THE INVENTION

A first aspect of the present invention is a photomask, comprising: a substrate transparent to a selected wavelength or wavelengths of radiation, the substrate having a top surface and an opposite bottom surface, the substrate having a printable region and a non-printable region; the printable region having first opaque regions raised above the top surface of the substrate adjacent to clear regions, each opaque region of the first opaque regions having sidewalls and opposite top and bottom surfaces, the first opaque regions comprising a metal; the non-printable region comprising metal second opaque region raised above the top surface of the substrate, the second opaque region having sidewalls and opposite top and bottom surface, the second opaque regions comprising the metal; and a conformal protective metal oxide capping layer on top surfaces and sidewalls of the first and second opaque regions.

A second aspect of the present invention is a method of fabricating a photomask, comprising: on a substrate transparent to a selected wavelength or wavelengths of radiation, the substrate having a top surface and an opposite bottom surface, defining a printable region and a non-printable region; forming in the printable region, first opaque regions raised above the top surface of the substrate adjacent to clear regions, each opaque region of the first opaque regions having sidewalls and opposite top and bottom surfaces, the first opaque regions comprising a metal; forming in the non-printable region, metal second opaque region raised above the top surface of the substrate, the second opaque region having sidewalls and opposite top and bottom surface, the second opaque regions comprising the metal; and forming a protective metal oxide capping layer on top surfaces and sidewalls of the first and second opaque regions.

### BRIEF DESCRIPTION OF THE DRAWINGS

The features of the invention are set forth in the appended claims. The invention itself, however, will be best understood by reference to the following detailed description of an illustrative embodiment when read in conjunction with the accompanying drawings, wherein:

FIGS. 1A and 1B are cross-sectional views illustrating fabrication of a binary photomask according to the present invention;

FIGS. 2A and 2B are cross-sectional views illustrating fabrication of an alternating phase shift mask photomask according to the present invention;

FIG. 3 is a cross-sectional view of an alternative alternating phase shift mask photomask according to the present invention;

FIG. 4 is a magnified cross-sectional view of an edge of an opaque region of an alternating phase shift mask photomask according to the present invention; and

FIG. 5 is a cross-sectional view of illustrating an alternative starting layer for FIG. 1A according to the present invention.

### DETAILED DESCRIPTION OF THE INVENTION

In a binary mask the opaque regions have, in one example, pass essentially none of a selected wavelength or group of wavelengths of optical radiation, i.e. the mask design wavelength(s) and the clear regions pass, in one example, about 99% or more of the optical radiation.

In an alternating phase-shift mask, the radiation passing through the thinned clear regions (passing about 99% or more of the optical radiation) of the substrate undergoes a phase shift relative to the phase of the radiation passing through the non-thinned clear regions. The opaque regions have, in one example, an essentially zero radiation transmission level.

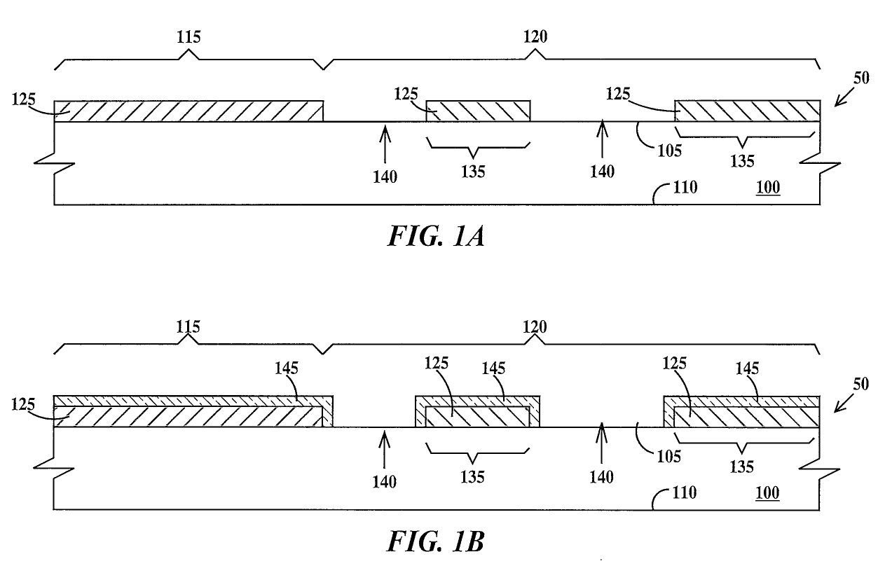

FIGS. 1A and 1B are cross-sectional views illustrating fabrication of a binary photomask according to the present invention. In FIG. 1A, a photomask 50 comprises a quartz or glass substrate 100 having a top surface 105 and a bottom surface 110. Photomask 50 includes a non-printable region 115 and a printable region 120. In one example, non-printable-region 115 surrounds the entire periphery of printable region 120. Non-printable region 115 comprises an opaque layer 125 on top surface 105 of substrate 100. Opaque layer 125 and opaque regions 135 have a top surface 126 and sidewalls 127. Formed in printable region 120 is a pattern of opaque regions 135 and clear regions 140 corresponding to a pattern of shapes to be transferred to a wafer by a photolithographic process using photomask 50.

In one example, substrate 100 comprises quartz or glass. In one example opaque layer 125 comprises a metal. In one example, opaque layer 125 is chrome formed by evaporation or sputter deposition. Chrome is particularly reactive under semiconductor device fabrication conditions and application of the embodiments of the present invention to chrome containing masks is particularly advantageous. In one example, opaque layer 125 is between about 300 Å and about 1000 Å thick.

The pattern of opaque regions 135 and clear regions 140 may be formed by (1) forming a metal (e.g. chrome) layer on the substrate and a photoresist layer on the metal layer, (2) exposing selected regions of the photoresist layer to optical or e-beam radiation, (3) developing the photoresist layer, (4) etching away the metal where layer where it is not protected by photoresist, and (5) removing any remaining photoresist.

In FIG. 1B, a conformal protective capping layer 145 is formed on all exposed surfaces of opaque regions 135. Protective capping layer 145 comprises a metal oxide formed in situ by oxidizing the exposed surfaces of the opaque regions in an oxygen or water vapor atmosphere at elevated temperatures. When opaque regions 135 are chrome, protective capping layer 145 comprises a chrome oxide and may be formed, for example, it may be formed heating mask 50 to about 500° C. in an oxygen or water vapor atmosphere or in a in an oxygen or water vapor atmosphere including hydrogen, nitrogen, or an inert gas such as helium or argon. In one example, protective capping layer 145 is between about 10 Å and about 50 Å thick. Protective capping layer 145 prevents the material (e.g. Cr) in opaque regions 135 from chemical attack and prevents the top surface of clear regions 140 from contamination and acts to prevent reflections from light in the lithography tool which may impinge upon the top surface of the reticle. Protective capping layer 145 should be thick enough to prevent diffusion of underlying layers but thin enough not to effect printed images.

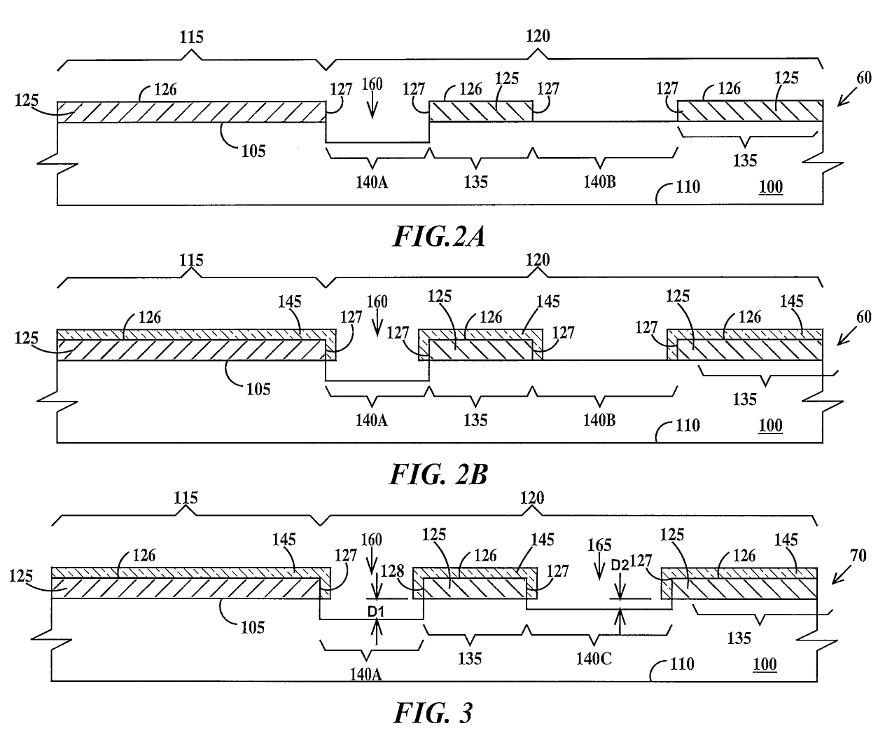

FIGS. 2A and 2B are cross-sectional views illustrating fabrication of an alternating phase shift mask photomask according to the present invention. In FIG. 2A, a photomask 60 comprises substrate 100 having non-printable region 115 and printable region 120. Non-printable region 115 comprises an opaque layer 125. Formed in printable region 120 is a pattern of opaque regions 135, thinned clear regions 140A and clear regions 140B corresponding to a pattern of shapes to be transferred to a wafer by a photolithographic process using photomask 60.

Photomask 60 may be formed from photomask 50 illustrated in FIG. 1A and described supra by protecting some clear regions 140 (see FIG. 1A) with photoresist and etching into substrate 100 to form trenches 160 where an opening has been lithographically formed in the photoresist layer and then removing the photoresist.

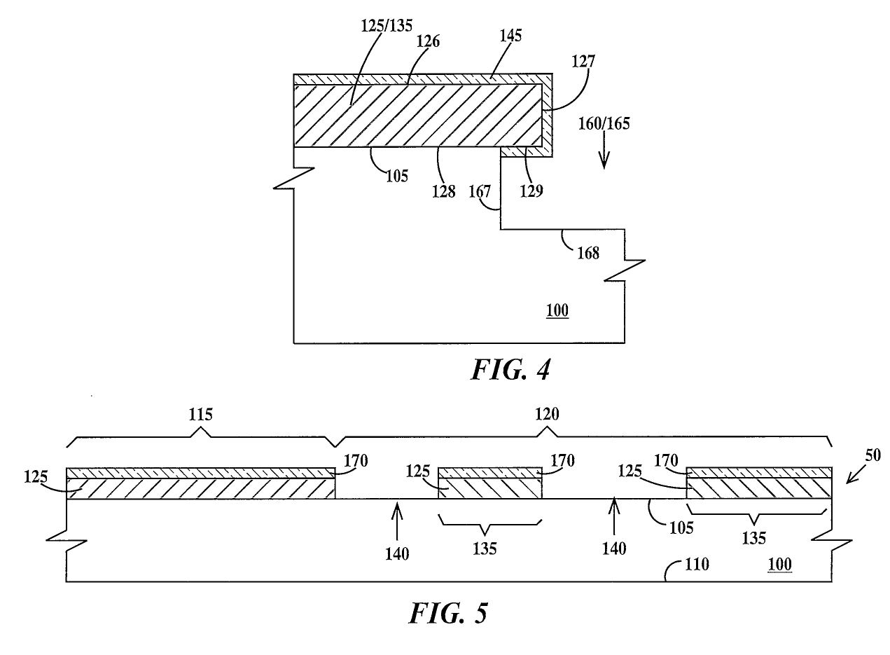

In FIG. 2B, conformal protective capping layer 145 is formed on all exposed surfaces of opaque layer 125 and opaque regions 135 as described supra in reference to FIG. 1B. See FIG. 4 and description infra.

FIG. 3 is a cross-sectional view of an alternative alternating phase shift mask photomask according to the present invention. In FIG. 3, a photomask 70 is similar to photomask 60 of FIG. 3, except clear regions 140B of FIG. 2B are replaced with thinned clear regions 140C. Thinned cleared regions 140A are thinner then thinned cleared regions 140C. Thinned clear regions 140A extend a distance D1 from top surface 105 of substrate 100 into the substrate while thinned clear regions 140B extend a distance D2 from top surface 105 of substrate 100 into the substrate with D1>D2. Fabrication of photomask 70 is similar to fabrication of photomask 60 described supra, except two photolithographic/substrate etch steps are required, one for forming thinned regions 140A and one for forming thinned regions 140C. Alternatively, region 140A can be formed as described supra, but to a depth of D1-D2, then the entire substrate can be subjected to an etch, forming clear regions 140C to a depth of D2, while making thinned clear regions 140A the final depth of D1.

FIG. 4 is a magnified cross-sectional view of an edge of an opaque region of an alternating phase shift mask photomask according to the present invention. In FIG. 4, it can be opaque layer 125/opaque region 135 has a bottom surface 128 opposite top surface 126. A portion 129 of bottom surface 128 overhangs a bottom surface 168 of trench 160/165. Protective capping layer 145 is formed all exposed surfaces of opaque layer 125/opaque region 135 including top surface 126, sidewall 127 and portion 129 of bottom surface 129.

FIG. 5 is a cross-sectional view of illustrating an alternative starting layer for FIG. 1A according to the present invention. In FIG. 5, a chrome oxide layer 170 was formed on opaque layer 125 prior to defining opaque regions 135 and clear regions 140. In the example that opaque layer 125 is chrome, then oxide layer 170 is chrome oxide in which case chrome oxide from layer 170 would be incorporated into capping layer 145 (see FIG. 1B) on the top surfaces of opaque regions 135 while capping layer 145 formed on the sidewalls of the opaque regions would formed only from layer 125. If layer 170 is sufficiently thick, no significant additional chrome oxide will be formed on the top surfaces of opaque regions 135 in FIG. 1B. This alternative is also applicable to the second embodiment of the present invention.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A photomask, comprising:
a substrate transparent to a selected wavelength or wavelengths of radiation, said substrate having a top surface and an opposite bottom surface, said substrate having a printable region and a non-printable region;
said printable region having first opaque regions raised above said top surface of said substrate adjacent to clear regions, each opaque region of said first opaque regions having sidewalls and opposite top and bottom surfaces, said first opaque regions comprising a metal;
said non-printable region comprising metal second opaque region raised above said top surface of said substrate, said second opaque region having sidewalls and opposite top and bottom surface, said second opaque regions comprising said metal; and
a conformal protective metal oxide capping layer on top surfaces and sidewalls of said first and second opaque regions.

2. The photomask of claim 1, further including:
said printable region divided into first printable regions and second printable regions; and
trenches extending from said top surface of said substrate into said substrate in said first printable regions where said substrate is not covered by said first opaque regions, said bottom surfaces of said first opaque regions covered by said capping layer where said bottom surfaces of said first opaque regions overhang said trenches.

3. The photomask of claim 1, further including:
said printable region divided into first printable regions and second printable regions;
a first set of trenches extending from said top surface of said substrate into said substrate in said first printable regions where said substrate is not covered by said first opaque regions, said bottom surfaces of said first opaque regions covered by said capping layer where said bottom surfaces of said first opaque regions overhang said trenches;
a second set of trenches extending from said top surface of said substrate into said substrate in said second printable regions where said substrate is not covered by said first opaque regions, said bottom surfaces of said first opaque regions covered by said capping layer where said bottom surfaces of said first opaque regions overhang said trenches; and
wherein said trenches of said first set of trenches extend into said substrate a first distance from said top surface of said substrate, said trenches of said second set of trenches extend into said substrate a second distance from said top surface of said substrate, said first distance different from said second distance.

4. The photomask of claim 1, wherein said protective capping layer comprises an oxide of said metal.

5. The photomask of claim 1, wherein said metal comprises chrome and said protective capping layer comprises chrome oxide.

6. The photomask of claim 1, wherein said capping layer has a thickness between about 10 Å and about 50 Å.

7. A method, comprising:
on a substrate transparent to a selected wavelength or wavelengths of radiation, said substrate having a top surface and an opposite bottom surface, defining a printable region and a non-printable region;
forming in said printable region, first opaque regions raised above said top surface of said substrate adjacent to clear regions, each opaque region of said first opaque regions having sidewalls and opposite top and bottom surfaces, said first opaque regions comprising a metal;
forming in said non-printable region, metal second opaque region raised above said top surface of said substrate, said second opaque region having sidewalls and opposite top and bottom surface, said second opaque regions comprising said metal; and
forming a protective metal oxide capping layer on top surfaces and sidewalls of said first and second opaque regions.

8. The method of claim 7, further including:
dividing said printable region into first printable regions and second printable regions;
etching trenches into said substrate in said first printable regions where said substrate is not covered by said first opaque regions; and
where said forming said capping layer also forms said capping layer on said bottom surfaces of said first opaque regions that overhang said trenches.

9. The method of claim 7, further including:
dividing said printable region into first printable regions and second printable regions;
prior to forming said conformal layer, etching a first set of trenches into said substrate in said first printable regions where said substrate is not covered by said first opaque regions followed by etching a second set of trenches into said substrate in said second printable regions where said substrate is not covered by said first opaque regions;
after said forming said capping layer, said capping layer is formed on said bottom surfaces of said first opaque regions that overhang said first set of trenches and said capping layer is formed on said bottom surfaces of said second opaque regions that overhang said second set of trenches; and
wherein said trenches of said first set of trenches extend into said substrate a first distance from said top surface of said substrate, said trenches of said second set of trenches extend into said substrate a second distance from said top surface of said substrate, said first distance different from said second distance.

10. The method of claim 7, wherein said capping layer is formed by oxidation of exposed surfaces of said first and second opaque regions.

11. The method of claim 7, wherein said metal comprises chrome and said capping layer comprises chrome oxide formed by oxidation of exposed surfaces of said first and second opaque regions.

12. The method of claim 7, wherein said capping layer has a thickness between about 10 Å and about 50 Å.
